(19) United States
(12) Patent Application Publication
(10) Pub. No.: US 2025/0148173 A1
(43) Pub. Date: May 8, 2025

(54) METHOD AND SYSTEM FOR PREDICTING HYDRATION REACTION DEGREE OF CEMENT BASED ON CYCLEGAN

(71) Applicants: ZHENGZHOU UNIVERSITY, Zhengzhou City (CN); CHINA UNIVERSITY OF MINING AND TECHNOLOGY, Xuzhou City (CN)

(72) Inventors: Mingrui DU, Zhengzhou City (CN); Xupei YAO, Zhengzhou City (CN); Hongyuan FANG, Zhengzhou City (CN); Peng ZHAO, Zhengzhou City (CN); Haijian Su, Xuzhou City (CN); Niannian Wang, Zhengzhou City (CN); Xueming Du, Zhengzhou City (CN); Xiaohua ZHAO, Zhengzhou City (CN); Binghan Xue, Zhengzhou City (CN)

(73) Assignees: ZHENGZHOU UNIVERSITY, Zhengzhou City (CN); CHINA UNIVERSITY OF MINING AND TECHNOLOGY, Xuzhou City (CN)

(21) Appl. No.: 18/925,255

(22) Filed: Oct. 24, 2024

(30) Foreign Application Priority Data
Nov. 7, 2023 (CN) 202311477839.X

(51) Int. Cl. G06F 30/27; C04B 28/04; C04B 40/00

(52) U.S. Cl. CPC G06F 30/27; C04B 28/04; C04B 40/0032

(57) ABSTRACT

Provided is a method and system for predicting a hydration reaction degree of cement based on a cycle generative adversarial network (CycleGAN). The method includes the following steps: S1, acquiring a micro-structure image of a cement paste test specimen; S2, establishing a micro-pore structure image dataset; S3, establishing a cement micro-hydration prediction model based on a CycleGAN; and S4, completing prediction based on a final cement micro-hydration prediction model. A deep learning algorithm is applied to micro-hydration prediction of cement. A complex theoretical formula is replaced with a data driven mode. Dependence on ideal hypotheses is reduced, and the accuracy of prediction on micro-hydration of cement is thus improved.

### CROSS REFERENCE TO RELATED APPLICATION

This patent application claims the benefit and priority of Chinese Patent Application No. 202311477839.X, filed with the China National Intellectual Property Administration on Nov. 7, 2023, the disclosure of which is incorporated by reference herein in its entirety as part of the present application.

### TECHNICAL FIELD

The present disclosure relates to the technical field of cement materials, and in particular, to a method and system for predicting a hydration reaction degree of cement based on a cycle CycleGAN.

### BACKGROUND

Cement has the characteristics of composition diversification, microstructural multi-polarization, and the like, and hydration of cement is a highly complicated multi-phase physicochemical reaction process. Studies have showed that the development of various properties of cement is based on the hydration reaction process. Macro-properties of cement, as a composite material having multi-scale structural characteristics, are determined by micro-nano characteristics thereof. Therefore, the quantitative description of the hydration reaction process of cement in a parametric form is an important foundation of material design and performance evaluation, providing important basis for safety performance evaluation of infrastructures such as a building, a bridge, a tunnel, a sea, and a road.

At present, a micro-hydration prediction model for cement is employed to describe a time-varying law of hydration reaction by mainly using a complex mathematical formula. In a simulation process of micro-structure evolution of cement, a time step needs to be designed for an existing model to perform iterative operations. However, repeated iterations need to occupy a large number of computing resources such that simulation tends to be time-costing and labor-consuming. On the other hand, due to the complexity of hydration of cement, the establishment of a hydration prediction model is usually based on lots of idealized hypotheses, leading to reduced prediction accuracy.

### SUMMARY

To solve the problems in the prior art, the present disclosure provides a method and system for predicting a hydration reaction degree of cement based on a CycleGAN. The problems mentioned in the above background are solved.

To achieve the above objective, the present disclosure provides the following technical solution: a method for predicting a hydration reaction degree of cement based on a CycleGAN includes the following steps:
S1, acquiring a micro-structure image of a cement paste test specimen;
S2, establishing a micro-pore structure image dataset;
S3, establishing a cement micro-hydration prediction model based on a cycle generative adversarial network (CycleGAN); and
S4, completing prediction based on a final cement micro-hydration prediction model.

Preferably, step S1 specifically includes the following steps:
S11, prefabricating a plurality of groups of normal portland cement paste test specimens of different water cement ratios; and
S12, separately sampling the cement paste test specimens at curing ages of 1, 3, 7, 14, 28, and 168 days, and conducting visual micro-pore structure testing using a testing technique of low-melting-point metal pressing-in combined with a back scattering mode of a scanning electron microscope to obtain micro-pore structure images of the test specimens at different curing ages.

Preferably, step S2 includes: performing image enhancement on the micro-structure image obtained in step S1, and establishing the micro-pore structure image dataset of cement at different curing ages, where the data enhancement includes random cropping, random rotation, random horizontal flip, and random vertical flip.

Preferably, step S3 specifically includes:
S31, establishing 5 CycleGANs, and with the micro-structure image at day 1 as an input, generating micro-structure images at day 3, day 7, day 14, day 28, and day 168, thereby realizing in-situ prediction of micro-structure hydration of cement;
S32, based on image analysis, evaluating the quality of the generated images by comparing micro-structures of the generated images and an actual image obtained from the test specimen, and optimizing the corresponding CycleGANs according to analysis results; and
S33, repeating steps S31 and step S32 until parameter evaluation indicators of the generated images and the image of the test specimen in comparison meet an accuracy requirement (R²≥95% or RMSE≤5%), and using the current CycleGAN as the final cement micro-hydration prediction model.

Preferably, in step S32, the evaluating the quality of the generated images specifically includes determining, by comparison, errors between the micro-structure images generated by the CycleGANs and the corresponding actual micro-structure image in pore structure parameters of a porosity, a pore size distribution, and a morphological and spatial feature, where evaluation indicators are RMSE and R², which are defined as follows:

$$RMSE = \sqrt{\frac{1}{n} {\sum }_{i = 1}^{n} {( {x}_{i} - \hat{{x}_{i}} )}^{2}} \\ {R}^{2} = 1 - \frac{{\sum }_{i = 1}^{n} {( {x}_{i} - \hat{{x}_{i}} )}^{2}}{{\sum }_{i = 1}^{n} {( {x}_{i} - \overline{{x}_{i}} )}^{2}}$$

where xᵢ represents a porosity, a pore size distribution, or a morphological and spatial feature obtained from the actual image; x̅ᵢ represents an average value of a corresponding parameter in the actual image; \hat{x}ᵢ represents a porosity, a pore size distribution, or a morphological and spatial feature obtained from the generated image; and n represents a number of test data samples.

Preferably, in step S32, the CycleGAN includes two groups of generators (G_{A}, G_{B}) and discriminators (D_{A}, D_{B}); the CycleGAN is trained by optimizing a loss function composed of 1 cycle consistency loss [symbol] , 1 ontology mapping loss [symbol] , and 2 adversarial losses [symbol] , [symbol] , and by means of random inactivation and cross validation mechanisms; and
calculation formulas of [symbol] , [symbol] , and [symbol] are as follows:

$${ℒ}_{cyc} ( {G}_{A} , {G}_{B} ) = {E}_{{x}_{1 D} \sim {p}_{data} ( {x}_{1 D} )} [ {‖ {G}_{A} ( {G}_{B} ( {x}_{1 D} ) ) - {x}_{1 D} ‖}_{1} ] + {E}_{{x}_{HD} \sim {p}_{data} ( {x}_{HD} )} [ {‖ {G}_{B} ( {G}_{A} ( {x}_{HD} ) ) - {x}_{HD} ‖}_{1} ] \\ {ℒ}_{identity} ( {G}_{A} , {G}_{B} ) = {E}_{{x}_{1 D} \sim {p}_{data} ( {x}_{1 D} )} [ {‖ {G}_{A} ( {x}_{1 D} ) - {x}_{1 D} ‖}_{1} ] + {E}_{{x}_{HD} \sim {p}_{data} ( {x}_{HD} )} [ {‖ {G}_{B} ( {x}_{HD} ) - {x}_{HD} ‖}_{1} ] \\ {ℒ}_{GAN 1} ( {G}_{A} , {D}_{A} ) = {E}_{{x}_{HD} \sim {p}_{data} ( {x}_{HD} )} [ log ( {D}_{A} ( {x}_{HD} ) ) ] + {E}_{{x}_{1 D} \sim {p}_{data} ( {x}_{1 D} )} [ log ( 1 - {D}_{A} ( {G}_{A} ( {x}_{1 D} ) ) ] \\ {ℒ}_{GAN 2} ( {G}_{B} , {D}_{B} ) = {E}_{{x}_{1 D} \sim {p}_{data} ( {x}_{1 D} )} [ log ( {D}_{B} ( {x}_{1 D} ) ) ] + {E}_{{x}_{HD} \sim {p}_{data} ( {x}_{HD} )} [ log ( 1 - {D}_{B} ( {G}_{B} ( {x}_{HD} ) ) ]$$

where x_{1D} represents a micro-structure image of cement at the curing age of 1 day; x_{HD} represents a micro-structure image of cement at the curing age of 3 days, 7 days, 14 days, 28 days, or 168 days; operator E represents expected calculation; and ∥∥₁ represents L1 regularization.

Preferably, in step S4, the micro-structure image of cement at day 1 to be measured is input to the final cement micro-hydration prediction model to obtain in-situ micro-structure predicted images at days 3, 7, 14, 28, and 168.

In another aspect, to achieve the above objective, the present disclosure further provides the following technical solution: a system for predicting a hydration reaction degree of cement based on a CycleGAN includes:
an image acquisition module (110) configured to acquire a micro-structure image of a cement paste test specimen;
a dataset establishment module (120) configured to establish a micro-pore structure image dataset;
a prediction model establishment module (130) configured to establish a cement micro-hydration prediction model based on a CycleGAN; and
a prediction module (140) configured to complete prediction based on a final cement micro-hydration prediction model.

The present disclosure has following beneficial effects:
1) A deep learning algorithm is applied to micro-hydration prediction of cement. A complex theoretical formula is replaced with a data driven mode. Dependence on ideal hypotheses is reduced, and the accuracy of prediction on micro-hydration of cement is thus improved.
2) Compared with a traditional model that needs to predict the micro-hydration process of cement by multiple iterations, the model achieves end-to-end prediction of a changing process of the micro-structure of cement over hydration time in combination with an image domain migration theory in the field of deep learning and can significantly improve the prediction efficiency of the model.

### BRIEF DESCRIPTION OF THE DRAWINGS

FIG. 1 is flowchart of a method for predicting a hydration reaction degree of cement based on a CycleGAN according to the present disclosure; and

FIG. 2 is a schematic diagram of modules of a system for predicting a hydration reaction degree of cement based on a CycleGAN according to the present disclosure.

List of Reference Numerals: 110—image acquisition module, 120—dataset establishment module, 130—prediction model establishment module, and 140—prediction module.

### DETAILED DESCRIPTION OF THE EMBODIMENTS

The technical solutions of the embodiments of the present disclosure are clearly and completely described below with reference to the accompanying drawings. Apparently, the described embodiments are merely a part rather than all of the embodiments of the present disclosure. All other embodiments derived from the embodiments of the present disclosure by those skilled in the art without creative efforts shall fall within the protection scope of the present disclosure.

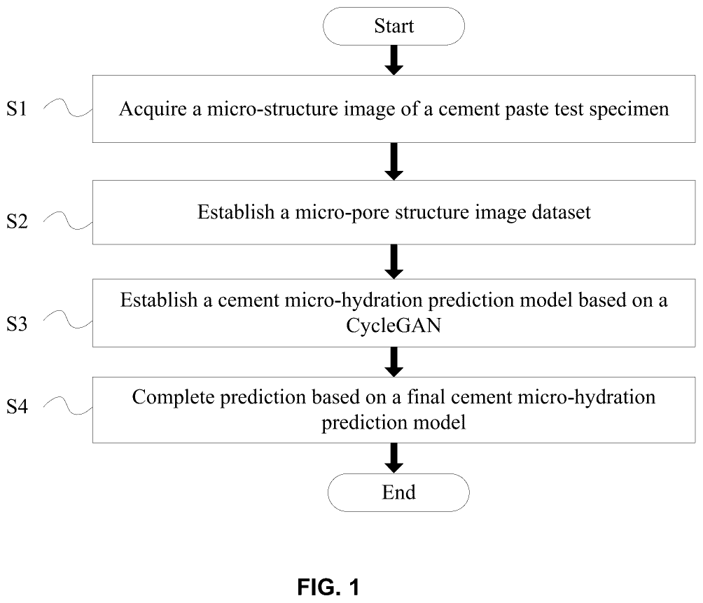

Referring to FIG. 1, the present disclosure provides a technical solution: a method for predicting a hydration reaction degree of cement based on a CycleGAN includes the following steps.

In step S1, a micro-structure image of a cement paste test specimen is acquired.

A plurality of groups of normal portland cement paste test specimens of different water cement ratios (the water cement ratios are 0.2, 0.3, 0.4, and 0.5) are prefabricated.

The cement paste test specimens at curing ages of 1, 3, 7, 14, 28, and 168 days are separately sampled, and visual micro-pore structure testing is conducted using a testing technique of low-melting-point metal pressing-in combined with a back scattering mode of a scanning electron microscope to obtain micro-pore structure images of the test specimens at different curing ages.

In step S2, a micro-pore structure image dataset is established.

Further, image enhancement is performed on the micro-structure image obtained in step S1, and the micro-pore structure image dataset of cement at different curing ages is established.

The data enhancement includes random cropping, random rotation, random horizontal flip, and random vertical flip.

In step S3, a cement micro-hydration prediction model based on a CycleGAN is established.

In step S31, 5 CycleGANs are established; mapping relationships of a micro-structure image at day 1 with images at day 3, day 7, day 14, day 28, and day 168 in a higher dimensional space are learned separately, and an image style migration theory is combined. With the micro-structure image at day 1 as an input, micro-structure images at day 3, day 7, day 14, day 28, and day 168 are generated, thereby realizing in-situ prediction of micro-structure hydration of cement.

In step S32, based on image analysis, the quality of the generated images is evaluated by comparing micro-structures of the generated images and an actual image obtained from the test specimen, and the corresponding CycleGANs are optimized according to analysis results.

Further, the evaluating the quality of the generated images specifically includes determining, by comparison, errors between the micro-structure images generated by the CycleGANs and the corresponding actual micro-structure image in pore structure parameters of a porosity, a pore size distribution, and a morphological and spatial feature, where evaluation indicators are RMSE and R². The quality of the generated images is evaluated by comparing these parameters with respect to RMSE and R². The evaluation indicators are defined as follows:

$$RMSE = \sqrt{\frac{1}{n} {\sum }_{i = 1}^{n} {( {x}_{i} - \hat{{x}_{i}} )}^{2}} \\ {R}^{2} = 1 - \frac{{\sum }_{i = 1}^{n} {( {x}_{i} - \hat{{x}_{i}} )}^{2}}{{\sum }_{i = 1}^{n} {( {x}_{i} - \overline{{x}_{i}} )}^{2}}$$

where x₁ represents a porosity, a pore size distribution, or a morphological and spatial feature obtained from the actual image; x̅ₗ represents an average value of a corresponding parameter in the actual image; \hat{x}ₗ represents a porosity, a pore size distribution, or a morphological and spatial feature obtained from the generated image; and n represents a number of test data samples.

RMSE reflects a deviation between a predicted value and a tested value. R² displays a linear correlation degree between a predicted value and a tested value. The smaller the RMSE and the closer to 1 the R², the better the performance of the prediction model.

Further, the CycleGAN includes two groups of generators (G_{A}, G_{B}) and discriminators (D_{A}, D_{B}). By means of a domain transformation theory, the CycleGAN may establish a mapping relationship between unpaired image sets.

Further, the CycleGAN is trained by optimizing a loss function composed of 1 cycle consistency loss [symbol] , 1 ontology mapping loss [symbol] , and 2 adversarial losses [symbol] , [symbol] , and by means of random inactivation and cross validation mechanisms.

Further, calculation formulas of [symbol] , [symbol] , and [symbol] are as follows:

$${ℒ}_{cyc} ( {G}_{A} , {G}_{B} ) = {E}_{{x}_{1 D} \sim {p}_{data} ( {x}_{1 D} )} [ {‖ {G}_{A} ( {G}_{B} ( {x}_{1 D} ) ) - {x}_{1 D} ‖}_{1} ] + {E}_{{x}_{HD} \sim {p}_{data} ( {x}_{HD} )} [ {‖ {G}_{B} ( {G}_{A} ( {x}_{HD} ) ) - {x}_{HD} ‖}_{1} ] \\ {ℒ}_{identity} ( {G}_{A} , {G}_{B} ) = {E}_{{x}_{1 D} \sim {p}_{data} ( {x}_{1 D} )} [ {‖ {G}_{A} ( {x}_{1 D} ) - {x}_{1 D} ‖}_{1} ] + {E}_{{x}_{HD} \sim {p}_{datat} ( {x}_{HD} )} [ {‖ {G}_{B} ( {x}_{HD} ) - {x}_{HD} ‖}_{1} ] \\ {ℒ}_{GAN 1} ( {G}_{A} , {D}_{A} ) = {E}_{{x}_{HD} \sim {p}_{data} ( {x}_{HD} )} [ log ( {D}_{A} ( {x}_{HD} ) ) ] + {E}_{{x}_{1 D} \sim {p}_{data} ( {x}_{1 D} )} [ log ( 1 - {D}_{A} ( {G}_{A} ( {x}_{1 D} ) ) ] \\ {ℒ}_{GAN 2} ( {G}_{B} , {D}_{B} ) = {E}_{{x}_{1 D} \sim {p}_{data} ( {x}_{1 D} )} [ log ( {D}_{B} ( {x}_{1 D} ) ) ] + {E}_{{x}_{HD} \sim {p}_{data} ( {x}_{HD} )} [ log ( 1 - {D}_{B} ( {G}_{B} ( {x}_{HD} ) ) ]$$

where x_{1D} represents a micro-structure image of cement at the curing age of 1 day; x_{HD} represents a micro-structure image of cement at the curing age of 3 days, 7 days, 14 days, 28 days, or 168 days; operator E represents expected calculation; and ∥∥₁ represents L1 regularization.

In the training process, the loss function is optimized using an Adam optimizer. The robustness and the generalization performance of the model are improved by means of training mechanisms such as random inactivation and cross validation.

In step S33, steps S31 and step S32 are repeated until parameter evaluation indicators of the generated images and the image of the test specimen in comparison meet an accuracy requirement (R²≥95% or RMSE≤5%), and the current CycleGAN is used as the final cement micro-hydration prediction model.

In step S4, prediction is completed based on a final cement micro-hydration prediction model.

The micro-structure image of cement at day 1 to be measured is input to the final cement micro-hydration prediction model to obtain in-situ micro-structure predicted images at days 3, 7, 14, 28, and 168.

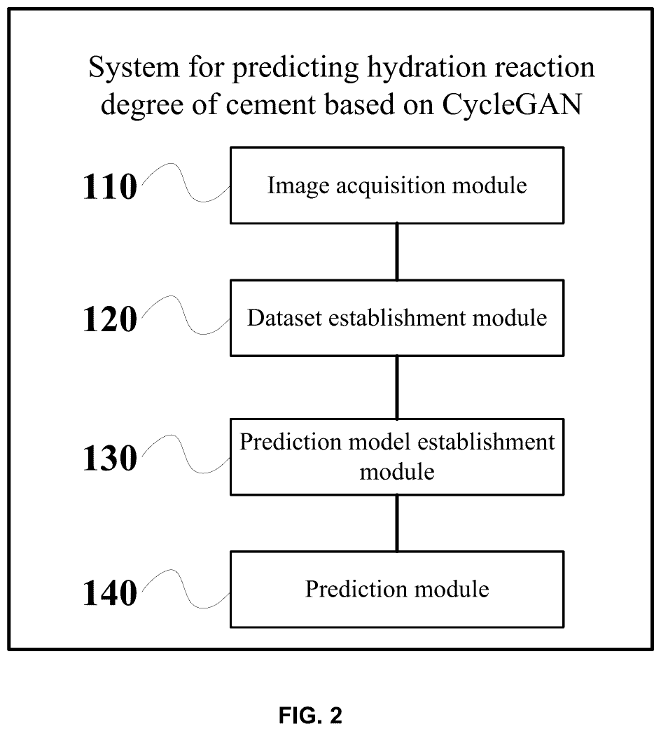

Based on the same inventive concept with the above method embodiment, an embodiment of the present disclosure further provides a system for predicting a hydration reaction degree of cement based on a CycleGAN. The system may implement the functions provided by the above method embodiment. As shown in FIG. 2, the system includes:
an image acquisition module (110) configured to acquire a micro-structure image of a cement paste test specimen;
a dataset establishment module (120) configured to establish a micro-pore structure image dataset;
a prediction model establishment module (130) configured to establish a cement micro-hydration prediction model based on a CycleGAN; and
a prediction module (140) configured to complete prediction based on a final cement micro-hydration prediction model.

A deep learning algorithm is applied to micro-hydration prediction of cement. A complex theoretical formula is replaced with a data driven mode. Dependence on ideal hypotheses is reduced, and the accuracy of prediction on micro-hydration of cement is thus improved. Compared with a traditional model that needs to predict the micro-hydration process of cement by multiple iterations, the model achieves end-to-end prediction of a changing process of the micro-structure of cement over hydration time in combination with an image domain migration theory in the field of deep learning and can significantly improve the prediction efficiency of the model.

Although the present disclosure has been described in detail with reference to the aforementioned embodiments, those skilled in the art can still modify the technical solutions described in the aforementioned embodiments, or substitute some of the technical features of the embodiments. Any modifications, equivalent substitutions, improvements, etc. within the spirit and scope of the present disclosure are intended to be included in the claimed scope of the present disclosure.

What is claimed is:

1. A method for predicting a hydration reaction degree of cement based on a cycle generative adversarial network (CycleGAN), comprising the following steps:
S1, acquiring a micro-structure image of a cement paste test specimen;
S2, establishing a micro-pore structure image dataset;
S3, establishing a cement micro-hydration prediction model based on a CycleGAN; and
S4, completing prediction based on a final cement micro-hydration prediction model.

2. The method for predicting a hydration reaction degree of cement based on a CycleGAN according to claim 1, wherein step S1 specifically comprises:
S11, prefabricating a plurality of groups of normal portland cement paste test specimens of different water cement ratios; and
S12, separately sampling the cement paste test specimens at curing ages of 1, 3, 7, 14, 28, and 168 days, and conducting visual micro-pore structure testing using a testing technique of low-melting-point metal pressing-in combined with a back scattering mode of a scanning electron microscope to obtain micro-pore structure images of the test specimens at different curing ages.

3. The method for predicting a hydration reaction degree of cement based on a CycleGAN according to claim 1, wherein step S2 comprises: performing image enhancement on the micro-structure image obtained in step S1, and establishing the micro-pore structure image dataset of cement at different curing ages, wherein the data enhancement comprises random cropping, random rotation, random horizontal flip, and random vertical flip.

4. The method for predicting a hydration reaction degree of cement based on a CycleGAN according to claim 1, wherein step S3 specifically comprises:
S31, establishing 5 CycleGANs, and with the micro-structure image at day 1 as an input, generating micro-structure images at day 3, day 7, day 14, day 28, and day 168, thereby realizing in-situ prediction of micro-structure hydration of cement;
S32, based on image analysis, evaluating the quality of the generated images by comparing micro-structures of the generated images and an actual image obtained from the test specimen, and optimizing the corresponding CycleGANs according to analysis results; and
S33, repeating steps S31 and step S32 until parameter evaluation indicators of the generated images and the image of the test specimen in comparison meet an accuracy requirement, and using the current CycleGAN as the final cement micro-hydration prediction model.

5. The method for predicting a hydration reaction degree of cement based on a CycleGAN according to claim 4, wherein in step S32, the evaluating the quality of the generated images specifically comprises determining, by comparison, errors between the micro-structure images generated by the CycleGANs and the corresponding actual micro-structure image in pore structure parameters of a porosity, a pore size distribution, and a morphological and spatial feature, wherein evaluation indicators are RMSE and R², which are defined as follows:
$$RMSE = \sqrt{\frac{1}{n} {\sum }_{i = 1}^{n} {( {x}_{i} - \hat{{x}_{i}} )}^{2}} \\ {R}^{2} = 1 - \frac{{\sum }_{i = 1}^{n} {( {x}_{i} - \hat{{x}_{i}} )}^{2}}{{\sum }_{i = 1}^{n} {( {x}_{i} - \overline{{x}_{i}} )}^{2}}$$
wherein xᵢ represents a porosity, a pore size distribution, or a morphological and spatial feature obtained from the actual image; x̅ₗ represents an average value of a corresponding parameter in the actual image; [symbol] represents a porosity, a pore size distribution, or a morphological and spatial feature obtained from the generated image; and n represents a number of test data samples.

6. The method for predicting a hydration reaction degree of cement based on a CycleGAN according to claim 4, wherein in step S32, the CycleGAN comprises two groups of generators (G_{A}, G_{B}) and discriminators (D_{A}, D_{B}); the CycleGAN is trained by optimizing a loss function composed of 1 cycle consistency loss [symbol] , 1 ontology mapping loss [symbol] , and 2 adversarial losses [symbol] , [symbol] , and by means of random inactivation and cross validation mechanisms; and
calculation formulas of [symbol] , [symbol] and [symbol] are as follows:
$${ℒ}_{cyc} ( {G}_{A} , {G}_{B} ) = {E}_{{x}_{1 D} \sim {p}_{data} ( {x}_{1 D} )} [ {‖ {G}_{A} ( {G}_{B} ( {x}_{1 D} ) ) - {x}_{1 D} ‖}_{1} ] + {E}_{{x}_{HD} \sim {p}_{data} ( {x}_{HD} )} [ {‖ {G}_{B} ( {G}_{A} ( {x}_{HD} ) ) - {x}_{HD} ‖}_{1} ] \\ {ℒ}_{identity} ( {G}_{A} , {G}_{B} ) = {E}_{{x}_{1 D} \sim {p}_{data} ( {x}_{1 D} )} [ {‖ {G}_{A} ( {x}_{1 D} ) - {x}_{1 D} ‖}_{1} ] + {E}_{{x}_{HD} \sim {p}_{data} ( {x}_{HD} )} [ {‖ {G}_{B} ( {x}_{HD} ) - {x}_{HD} ‖}_{1} ]$$
$${ℒ}_{GAN 1} ( {G}_{A} , {D}_{A} ) =$$
$${E}_{{x}_{HD} \sim {p}_{data} ( {x}_{HD} )} [ log ( {D}_{A} ( {x}_{HD} ) ) + {E}_{{x}_{1 D} \sim {p}_{data} ( {x}_{1 D} )} [ log ( 1 - {D}_{A} ( {G}_{A} ( {x}_{1 D} ) ) ]$$
$${ℒ}_{GAN 2} ( {G}_{B} , {D}_{B} ) = {E}_{{x}_{1 D} \sim {p}_{data} ( {x}_{1 D} )} [ log ( {D}_{B} ( {x}_{1 D} ) ) ] + {E}_{{x}_{HD} \sim {p}_{data} ( {x}_{HD} )} [ log ( 1 - {D}_{B} ( {G}_{B} ( {x}_{HD} ) ) ]$$
wherein x_{1D} represents a micro-structure image of cement at the curing age of 1 day; x_{HD} represents a micro-structure image of cement at the curing age of 3 days, 7 days, 14 days, 28 days, or 168 days; operator E represents expected calculation; and ∥∥₁ represents L1 regularization.

7. The method for predicting a hydration reaction degree of cement based on a CycleGAN according to claim 1, wherein in step S4, the micro-structure image of cement at day 1 to be measured is input to the final cement micro-hydration prediction model to obtain in-situ micro-structure predicted images at days 3, 7, 14, 28, and 168.

8. A system for predicting a hydration reaction degree of cement based on a CycleGAN, comprising:
an image acquisition module (110) configured to acquire a micro-structure image of a cement paste test specimen;
a dataset establishment module (120) configured to establish a micro-pore structure image dataset;
a prediction model establishment module (130) configured to establish a cement micro-hydration prediction model based on a CycleGAN; and
a prediction module (140) configured to complete prediction based on a final cement micro-hydration prediction model.
